(19) United States
(12) Patent Application Publication
(10) Pub. No.: US 2014/0042450 A1
(43) Pub. Date: Feb. 13, 2014

(54) SEMICONDUCTOR DEVICE AND MANUFACTURING METHOD OF THE SAME

(71) Applicant: KABUSHIKI KAISHA TOSHIBA, Tokyo (JP)

(72) Inventors: Kazuhiro AKIYAMA, Kanagawa (JP); Masanobu Ando, Fukuoka (JP); Gen Watari, Fukuoka (JP); Naoya Ushiyama, Fukuoka (JP); Shuji Itonaga, Kanagawa (JP)

(73) Assignee: Kabushiki Kaisha Toshiba, Tokyo (JP)

(21) Appl. No.: 13/784,739

(22) Filed: Mar. 4, 2013

(30) Foreign Application Priority Data
Aug. 10, 2012 (JP) 2012-178887

(51) Int. Cl. H01L 33/56; H01L 21/02; H01L 33/64; H01L 33/50

(52) U.S. Cl. CPC H01L 33/56; H01L 33/50; H01L 21/02518; H01L 33/64
USPC 257/76; 438/27; 438/478

(57) ABSTRACT

A semiconductor device is provided that includes a semiconductor layer and an electrode coupled to a semiconductor layer. The electrode includes first and second end portions, the first end portion being closer to the semiconductor layer than the second end portion. The first end portion is formed to have crystals of a first grain size, and the second end portion is formed to have crystals of a second grain size that is larger than the first grain size.

### CROSS-REFERENCE TO RELATED APPLICATION

This application is based upon and claims the benefit of priority from Japanese Patent Application No. 2012-178887, filed Aug. 10, 2012; the entire contents of which are incorporated herein by reference.

### FIELD

Embodiments described herein relate generally to a semiconductor device and a manufacturing method thereof.

### BACKGROUND

In the related art, semiconductor devices prepared by connecting electrodes to semiconductor layers and having them sealed off by a sealing resin body have been put into practical use. For such semiconductor devices, by reflow, the tips of the electrodes are jointed to the wiring of the assembling substrate via solder for assembling on the assembling substrate. However, due to the thermal stress generated between the semiconductor layer and the assembling substrate, the semiconductor device and the associated joint portion may be damaged.

### DESCRIPTION OF THE DRAWINGS

FIG. 1 is a cross-sectional view illustrating an example of a semiconductor device according to an embodiment.

FIG. 2 is a graph illustrating an example of a relationship between a plating rate and a crystal grain size according to an embodiment.

FIG. 3 is a schematic cross-sectional view illustrating a state after a thermal cycle test is carried out for a sample in a comparative example.

FIG. 4 is a cross-sectional view illustrating an example of a semiconductor device according to an embodiment.

FIGS. 5A-5D are cross-sectional views illustrating processes in an example of a manufacturing method of a semiconductor device according to an embodiment.

FIGS. 6A-6C are more cross-sectional views illustrating processes in an example of a manufacturing method of a semiconductor device according to an embodiment.

FIG. 7 is another cross-sectional view illustrating a process in an example of a manufacturing method of a semiconductor device according to an embodiment.

FIGS. 8A-8E are more cross-sectional views illustrating processes in an example of a manufacturing method of a semiconductor device according to an embodiment.

FIGS. 9A-9D are more cross-sectional views illustrating processes in an example of a manufacturing method of a semiconductor device according to an embodiment.

FIGS. 10A and 10B are more cross-sectional views illustrating processes in an example of a manufacturing method of a semiconductor device according to an embodiment.

FIGS. 11A and 11B are more cross-sectional views illustrating processes in an example of a manufacturing method of a semiconductor device according to an embodiment.

FIGS. 12A and 12B are more cross-sectional views illustrating processes in an example of a manufacturing method of a semiconductor device according to an embodiment.

FIGS. 13A and 13B are more cross-sectional views illustrating processes in an example of a manufacturing method of a semiconductor device according to an embodiment.

FIG. 14 is another cross-sectional view illustrating a process in an example of a manufacturing method of a semiconductor device according to an embodiment.

### DETAILED DESCRIPTION

Embodiments described herein provide a semiconductor device with high durability to thermal stress and a manufacturing method of. Embodiments are described below with reference to the drawings.

### General Overview

A semiconductor device according an embodiment has a semiconductor layer and an electrode coupled to a semiconductor layer. The electrode includes first and second end portions, the first end portion being closer to the semiconductor layer than the second end portion. The first end portion is formed to have crystals of a first grain size, and the second end portion is formed to have crystals of a second grain size that is larger than the first grain size.

A manufacturing method of a semiconductor device according to an embodiment includes forming a semiconductor layer, forming a first electrode portion on the semiconductor layer by a first electroplating method, and forming a second electrode portion on the first electrode portion by a second electroplating method, wherein an electroplating rate of the first electroplating method is lower than an electroplating rate of the second electroplating method.

Another manufacturing method of a semiconductor device according to an embodiment includes the following processes: forming a semiconductor layer on a first substrate, forming trenches to divide the semiconductor layer into several portions in an upper layer portion of the semiconductor layer and the first substrate, forming a wall-shaped member in an interior and upper portion of the trenches, forming a second substrate on the semiconductor layer, removing the first substrate, forming a protective film on a lower surface of the semiconductor layer, and removing the wall-shaped member.

### First Embodiment

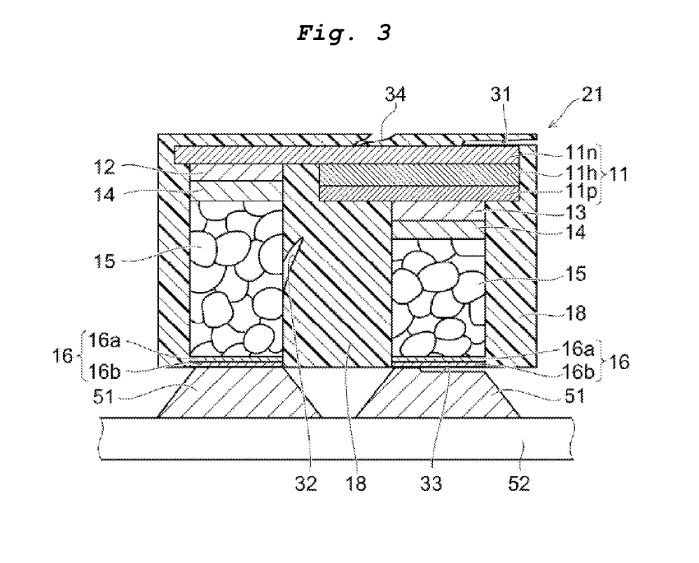

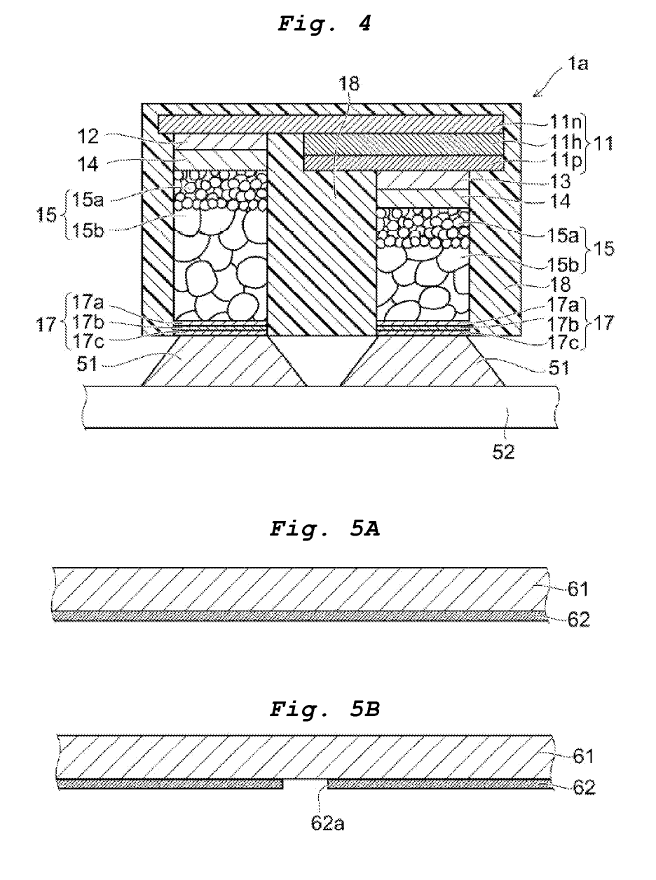

FIG. 1 is a cross-sectional view illustrating an example of a semiconductor device according to a first embodiment. As shown in FIG. 1, a crystal grain boundary is shown schematically for electrodes 15. FIGS. 3 and 4 are similar.

The semiconductor device 1 according to the first embodiment is assembled on an assembling substrate 52 via solder 51 for use. In the semiconductor device 1, a semiconductor layer 11 is arranged. The semiconductor layer 11 is an LED (light emitting device) layer that contains, for example, the nitride of group III (13^{th} group) element, such as gallium nitride (GaN), and emits blue light. In the semiconductor layer 11, an n-type layer 11n, a light emitting layer 11h, and a p-type layer 11p are laminated in order. For convenience of explanation, the side that is ahead in the direction from the semiconductor device 1 towards the assembling substrate 52 is referred to as “lower side”. However, it is irrelevant to the direction of gravity.

An n-type electrode 12 made of, for example, aluminum (Al), and a p-type electrode 13 made of, for example, silver (Ag) are arranged on the lower side of the semiconductor layer 11. The n-type electrode 12 is coupled to the lower surface of the n-type layer 11n. The p-type electrode 13 is coupled to the lower surface of the p-type layer 11p. A seed layer 14 is arranged on the lower side of each of the n-type electrode 12 and the p-type electrode 13. The seed layer 14 is, for example, a two-layer film prepared by laminating a titanium (Ti) layer and a copper layer. Here, the titanium layer is in contact with the n-type electrode 12 and the p-type electrode 13. The electrodes 15 made of, for example, copper (Cu) are arranged on the lower side of the seed layer 14. A metal film 16 is provided on the lower surface of the electrode 15. In the metal film 16, a nickel (Ni) layer 16a in contact with the electrode 15 and a gold (Au) layer 16b in contact with the nickel layer 16a are laminated in order. That is, the seed layer 14, the electrode 15 and the metal film 16 are arranged pair by pair.

Also, in the semiconductor device 1, a sealing resin body 18 is arranged to cover the semiconductor layer 11, the n-type electrode 12, the p-type electrode 13, the seed layer 14, the electrode 15 and the metal film 16. The lower surface of the gold layer 16b of the metal film 16 is exposed on the lower surface of the sealing resin body 18. The portion of the sealing resin body 18 arranged on the region right above the semiconductor layer 11 is made of a transparent resin, and a phosphor (not shown in the drawing) is dispersed in the portion.

In each electrode 15, the crystal grain size varies in the up/down direction. More specifically, the crystal grain size in an upper portion 15a of each electrode 15, that is, the crystal grain size in the portion of the electrode on the side near the semiconductor layer 11, is smaller than the crystal grain size at a lower portion 15b of the electrode 15, that is, the crystal grain size in the portion on the side opposite to the semiconductor layer 11. Here, the metal film 16 is formed on the end surface (lower surface) of the lower portion 15b of the electrode 15.

For example, the electrodes 15 may be formed by electroplating of copper on the seed layer 14.

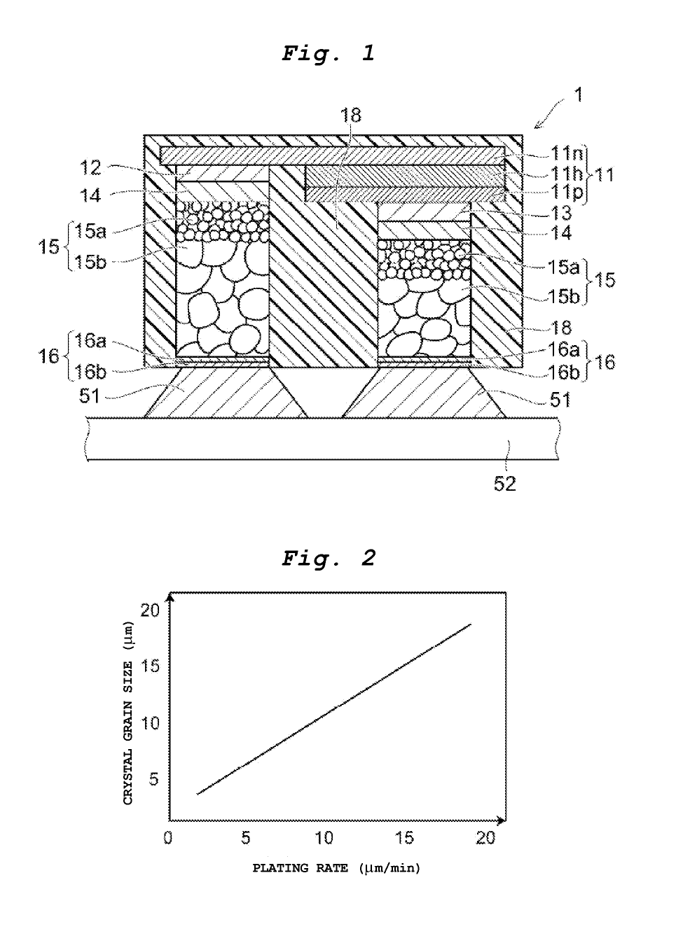

FIG. 2 is a graph illustrating an example of the relationship between a plating rate and a crystal grain size. In this graph, the abscissa represents the plating rate of copper (film forming rate), and the ordinate represents the crystal grain size in the formed copper film.

As shown in FIG. 2, the higher the copper plating rate, the larger the crystal grain size of the formed copper film. Consequently, when the copper film is plated on the seed layer 14, the copper film is formed at a lower plating rate so as to form the upper portion 15a with a smaller crystal grain size. Then, the copper film is formed at a higher plating rate to form the lower portion 15b with a larger crystal grain size. In this way, it is possible to form the electrodes 15 having different crystal grain sizes in the upper/lower portions, respectively.

The operation and effects of the present embodiment are explained below.

The semiconductor device 1 is assembled on the assembling substrate 52 by joining the lower end portion of each electrode 15 on the wiring (not shown in the drawing) of the assembling substrate 52 via a metal film 16 and a solder 51. For example, tips of the electrodes 15 (e.g., a second end portion) are coupled to a wiring of the assembling substrate 52 by way of solder 51. In this case, a thermal stress takes place between the semiconductor device 1 and the assembling substrate 52. Then, the assembled semiconductor device 1 is turned on by supplying electric power from the wiring of the assembling substrate 52 to the semiconductor layer 11 via the solder 51, the metal film 16, the electrodes 15, the seed layer 14, and the p-type electrode 13 or the n-type electrode 12. In this case, in company with on/off of power supply, the temperature in the semiconductor layer 11 changes up/down, so that a thermal stress is generated between the semiconductor layer 11 and the assembling substrate 52 and inside the semiconductor device 1.

In the semiconductor device 1 of the present embodiment, the crystal grain size of the upper portion 15a of each electrode 15 is smaller, so that it is possible to absorb the generated thermal stress better than the case when the entirety of the electrode 15 has the same crystal grain size. A cause is as follows: the copper crystals that form the upper portion 15a can make relative movement within a certain range, so that the thermal stress can be relaxed. Consequently, the semiconductor device 1 according to the present embodiment has a high durability to the thermal stress.

On the other hand, for the semiconductor device 1 according to the present embodiment, the lower portion 15b of each electrode 15 is formed at a higher film forming rate, so that the crystals have a larger crystal grain size. As a result, compared with the case when the overall electrode 15 is formed at a lower film forming rate and all of the crystal grains in each electrode 15 have a smaller size, in the present case, the electrodes 15 can be formed at a higher efficiency. Consequently, it is possible to cut the manufacturing cost of the semiconductor device 1.

A test example illustrating the relationship between the crystal grain size of each electrode and the durability to thermal stress are explained below.

FIG. 3 is a schematic cross-sectional view illustrating a state after a thermal cycle test for samples in a comparative example.

As the semiconductor layer 11, an LED layer that emits blue light is formed, and the n-type electrode 12 and the p-type electrode 13 are formed on the lower surface of this LED layer. Then, titanium on the lower surfaces of the n-type electrode 12 and the p-type electrode 13 is plated, and copper is plated, so that the seed layer 14 is formed. Then, on the lower surface of the seed layer 14, copper is plated to form the electrodes 15.

In this case, in the application example, after a copper film with a thickness of 10 μm is formed at a film forming rate of 1 μm/min, a copper film with a thickness of 100 μm is formed at a film forming rate of 10 μm/min. As a result, for each electrode 15, the crystal grain size in the upper portion 15a is smaller than the crystal grain size in the lower portion 15b. On the other hand, in the comparative example, a 110 μm-thick copper film is formed at a film forming rate of 10 μm/min. As a result, each electrode has nearly the same uniform crystal grain size, and the crystal grain size is almost equal to that of the lower portion of the electrodes in the application example. Here, the crystal grain size of the electrodes can be confirmed by a transmissive electron microscope or an X-ray topography.

Then, on each electrode 15, the nickel layer 16a is formed, and the gold layer 16b is formed, so that the metal film 16 is formed. Then, the semiconductor layer 11, then-type electrode 12, the p-type electrode 13, the seed layer 14, the electrode 15 and the metal film 16 are sealed off by a resin. By removing the resin from the lower surface of the metal film 16, the sealing resin body 18 is formed. As a result, the semiconductor device 1 according to the application example and a semiconductor device 21 according to the comparative example are manufactured, respectively.

Then, the semiconductor device 1 and the semiconductor device 21 manufactured above each are placed on an assembling substrate 52. In this case, the metal film 16 contacts the solder 51 arranged on the assembling substrate 52. Then, the assembling substrate having the semiconductor device placed thereon is loaded in a reflow oven. As a result, the solder is melted and then re-solidified, so that the metal film 16 is soldered on the wiring of the assembling substrate 52, and the electrodes 15 are coupled to the wiring of the assembling substrate 52 via the metal film 16 and the solder 51. As a result, the semiconductor device 1 and the semiconductor device 21 each are assembled on the assembling substrate 52. Then, for each of the samples obtained by assembling the semiconductor device on the assembling substrate 52, a thermal cycle test is carried out between temperatures at −40° C. to temperatures at +120° C. for 1000 cycles.

As shown in FIG. 3, for the samples in the comparative example, the following problems (1) to (5) can take place:

(1) separation 31 between the sealing resin body 18 and the semiconductor layer 11,

(2) separation 32 between the sealing resin body 18 and the electrode 15,

(3) separation 33 between the metal film 16 and the solder 51,

(4) cracks 34 on the sealing resin body 18, and

(5) decrease in light emitting output power of the semiconductor device 21.

On the other hand, for the samples according to present embodiments, none of the above-listed problems (1) to (5) takes place.

In the first embodiment, an example of the electrodes 15 being made of copper has been shown. However, the material for making the electrodes 15 is not limited to copper. In the first embodiment, an example has also been shown in which, for each of the electrodes 15, the crystal grain sizes of the two stages, that is, the upper portion 15a and the lower portion 15b, are different from each other. However, this is merely an example, and the present disclosure is not limited to the scheme. For example, the crystal grain size of the electrode 15 may be different, for example, of more than 3 stages, or the crystal grain size may also vary continuously from the upper end to the lower end. In this case, too, the crystal grain size in the upper end portion of each electrode 15, that is, the crystal grain size in the end portion on the side near the semiconductor layer 11 is smaller than the crystal grain size in the lower end portion of each electrode 15, that is, in the end portion on the side opposite to the semiconductor layer 11.

In addition, the material for the semiconductor layer 11 is not limited to gallium nitride. For example, one may also use the nitrides of aluminum (Al), indium (In), and other group-III elements other than gallium (Ga). In addition, the layer structure of the seed layer 14 is not limited to the (Ti/Cu) two-layer structure. Any type of metal layer that can increase close contact property on the n-type electrode 12, the p-type electrode 13 and the electrode 15 and can suppress thermal diffusion of copper to the side of the semiconductor layer 11 can be used. For example, the seed layer 14 may also be a layer made of palladium (Pd), or a two-layer film prepared by laminating a titanium layer and a palladium layer.

In the following, a modified example of the first embodiment is explained.

FIG. 4 is a cross-sectional view illustrating an example of a semiconductor device according to the first embodiment.

As shown in FIG. 4, the semiconductor device 1a according to this modified example differs from the semiconductor device 1 according to the first embodiment (see FIG. 1) in that a metal film 17 is arranged instead of the metal film 16. The metal film 17 is formed by sequentially laminating the following layers from the side near the electrode 15: a nickel layer 17a, a palladium layer 17b and a gold layer 17c. Otherwise, the present modified example has the same constitution, operation and effects as those of the first embodiment.

### Second Embodiment

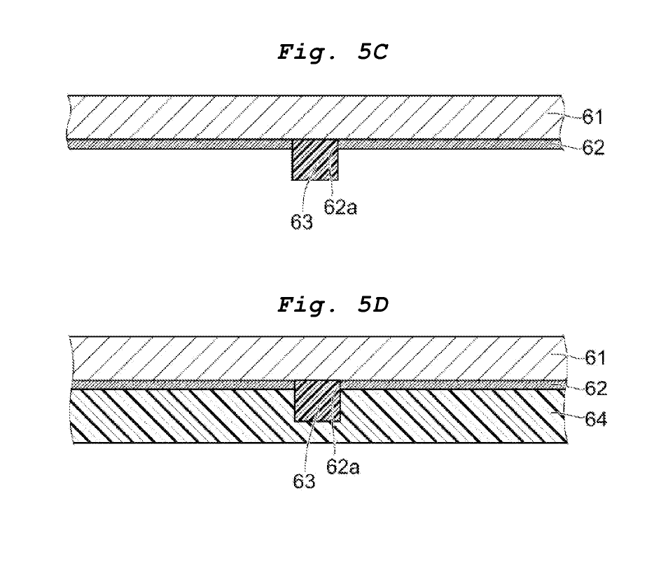

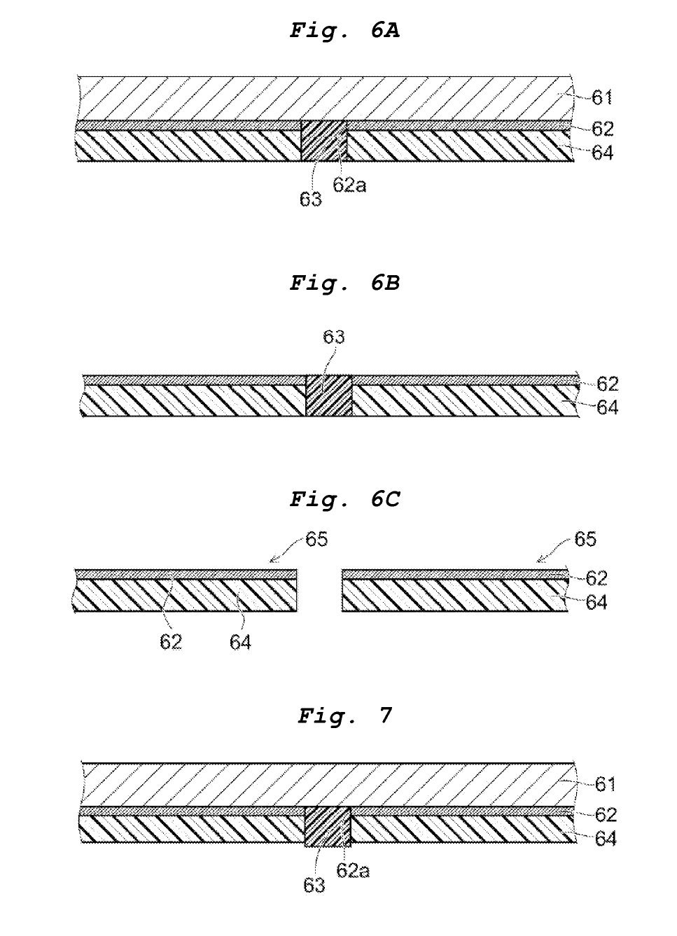

FIGS. 5A-5D and FIGS. 6A-6C are cross-sectional views illustrating processes in a manufacturing method of a semiconductor device according a second embodiment.

As shown in FIG. 5A, a silicon substrate 61 is prepared as the substrate for crystal growth. In addition to the silicon substrate, other types of substrates may also be adopted as the substrate for crystal growth, such as gallium arsenide (GaAs) substrate, alumina (Al₂O₃) substrate, gallium oxide (Ga₂O₃) substrate, zinc oxide (ZnO) substrate, silicon carbide (SiC) substrate, and diamond (C) substrate.

Then, on the upper surface of the silicon substrate 61, a semiconductor layer 62 is formed. For example, the semiconductor layer 62 is an LED layer, such as a layer containing InₓAl_{y}Ga_{z}N (x+y+z=1). In the following, according to the present embodiment, in order to facilitate explanation, the side that is ahead in the direction from the silicon substrate 61 towards the semiconductor layer 62 is referred to as “upper side”. This definition is also adopted in the third and the fourth embodiments to be explained later. This definition is opposite to that in the first embodiment and in FIG. 5A to FIG. 5D, etc. Also, this definition is irrelevant to the gravity direction.

In the following, as shown in FIG. 5B, etching is carried out by, for example, lithography, to form trenches 62a on the semiconductor layer 62. Here, the trenches 62a are formed to divide the semiconductor layer 62 to several portions. For example, they may be formed in a lattice configuration or a honeycomb shape.

Then, as shown in FIG. 5C, for example, by using the lithographic method, wall-shaped members 63 are formed in the interior and on the upper portion of the trenches 62a. The wall-shaped members have a wall shape surrounding the portions that have been partitioned by the trenches 62a in the semiconductor layer 62. The wall-shaped members 63 are made of a material that allows easy separation in the later process. For example, the wall-shaped members 63 may be made of a resin material or a metal material, such as one type of material selected from the group consisting of photosensitive resins and thermoplastic resins, or made of one or several types of metals selected from the group consisting of copper (Cu), aluminum (Al), titanium (Ti) and nickel (Ni), and, for example, wall-shaped members 63 may also be made of a resist material.

In the following, as shown in FIG. 5D, a reinforcing substrate 64 made of, for example, a resin material, is formed on the semiconductor layer 62 and the wall-shaped members 63 so as to cover the semiconductor layer 62 and the wall-shaped members 63.

Then, as shown in FIG. 6A, by grinding the upper surface of the reinforcing substrate 64, the reinforcing substrate 64 is made thinner. As a result, the wall-shaped members 63 are exposed on the upper surface of the reinforcing substrate 64.

Then, as shown in FIG. 6B, the silicon substrate 61 is removed. As a result, the wall-shaped members 63 are exposed on both the upper surface of the reinforcing substrate 64 and the lower surface of the semiconductor layer 62.

Then, as shown in FIG. 6C, for example, etching is carried out to remove the wall-shaped member 63. As a result, the laminate including the reinforcing substrate 64 and the semiconductor layer 62 is divided to several individual pieces. As a result, multiple semiconductor devices 65 are manufactured. In each of the semiconductor devices 65, the reinforcing substrate 64 and the semiconductor layer 62 are laminated.

In the following, the operation and effects of the present embodiment are explained below.

According to the present embodiment, without carrying out dicing, it is possible to manufacture multiple semiconductor devices 65 at the same time. As a result, it is possible to reduce the manufacturing cost of the semiconductor devices 65. When the trenches 62a and wall-shaped members 63 are formed, it is possible to adopt the lithographic method. Consequently, compared with the dicing method, it is possible to decrease the width of the portions to be removed from the reinforcing substrate 64 and the semiconductor layer 62. Consequently, it is possible to form more semiconductor devices 65 from a single wafer, so that it is possible to cut the manufacturing cost and material cost for each semiconductor device.

Also, according to the present embodiment, the wall-shaped members 63 can be formed en bloc and removed en bloc. Consequently, even when the semiconductor devices 65 are miniaturized, there is still no increase in the processing cost. On the other hand, when the semiconductor devices 65 are formed as individual pieces by dicing, in company with miniaturization of the semiconductor devices 65, the number of the dicing lines for each wafer increases, and the processing time becomes longer. Also, as the number of the semiconductor devices 65 for each wafer is increased, the width of the dicing portions becomes smaller, decreasing the yield. As a result, when the semiconductor devices are formed as individual pieces by dicing, various problems take place in company with miniaturization.

In addition, when the individual semiconductor devices are formed by dicing, the dicing lines should be straight lines that pass through the entirety of the wafer. On the other hand, according to the present embodiment, as the wall-shaped members 63 are formed by, for example, the lithographic method, the shape of the wall-shaped members 63 is not limited to the straight linear shape, so the degree of freedom of the layout is high. Consequently, the shape of the semiconductor devices 65 has a high degree of freedom. For example, one may also adopt a scheme in which the wall-shaped members 63 are formed in a honeycomb shape, and the semiconductor devices 65 are formed in a hexagonal shape.

In the following, a modified example of the present embodiment is explained.

FIG. 7 is a cross-sectional view illustrating a process in a manufacturing method of the semiconductor device a modified example of the second embodiment.

According to the present modified example, instead of the process shown in FIG. 5D and FIG. 6A in the second embodiment, the process shown in FIG. 7 is executed. That is, as shown in FIG. 7, when the reinforcing substrate 64 is formed, the thickness of the reinforcing substrate 64 is less than the height of the protrusion of the wall-shaped members 63. In this case, there is no need to carry out grinding for the reinforcing substrate 64 shown in FIG. 6A. As a result, according to the present modified example, different from the second embodiment, the process of grinding of the reinforcing substrate 64 can be omitted. The remaining features of the manufacturing method as well as the operation and effects in the modified example are the same as those in the second embodiment.

According to the second embodiment, the order of the process of grinding of the reinforcing substrate 64 shown in FIG. 6A and the process of removal of the silicon substrate 61 shown in FIG. 6B can be inverted. Also, instead of removal of the wall-shaped members 63 by etching, one may also adopt a scheme in which the wafer is expanded to have the wall-shaped members 63 detached from the laminate including the reinforcing substrate 64 and the semiconductor layer 62. In addition, the type of the semiconductor layer 62 is not limited to the LED layer.

### Third Embodiment

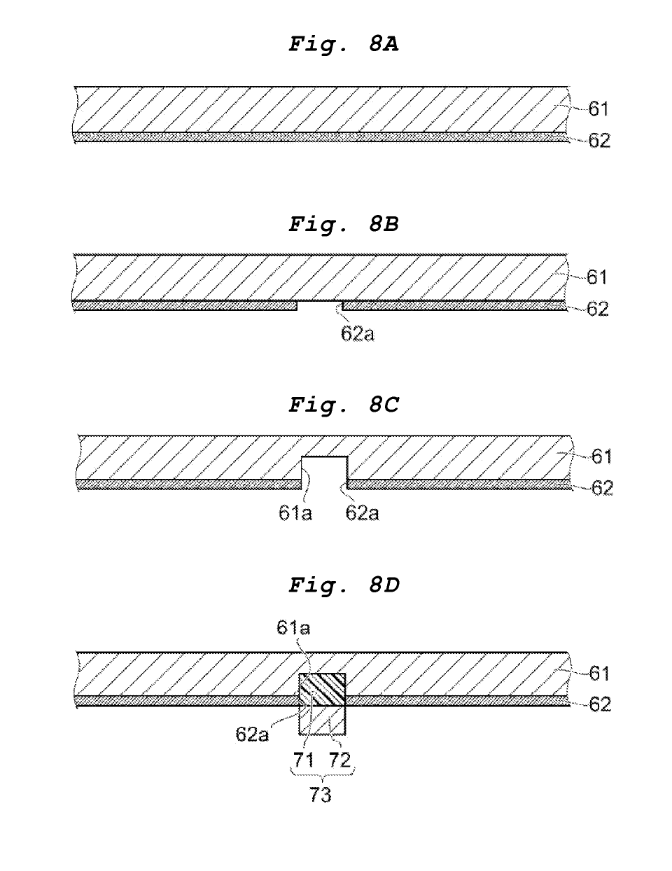

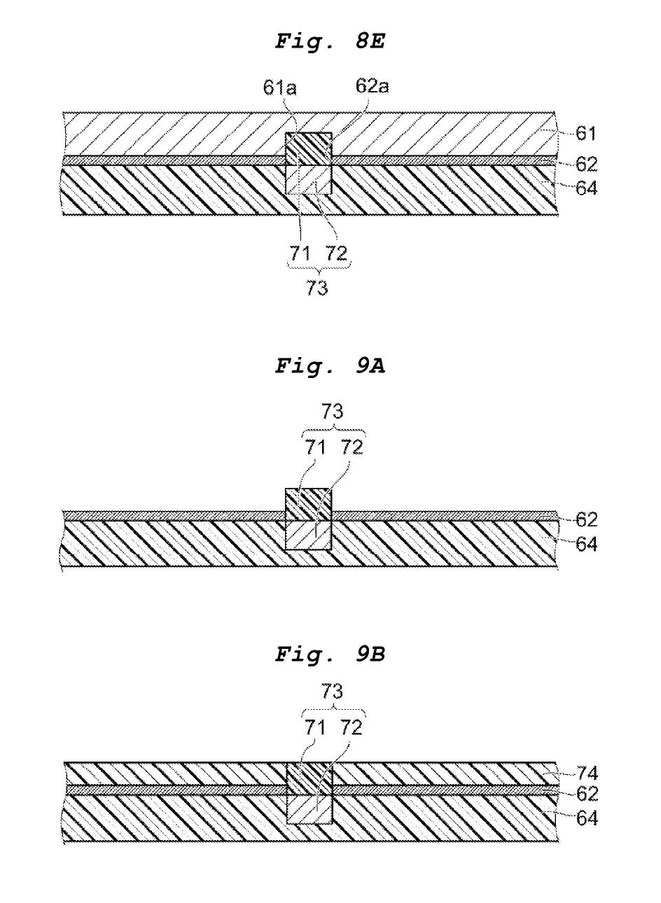

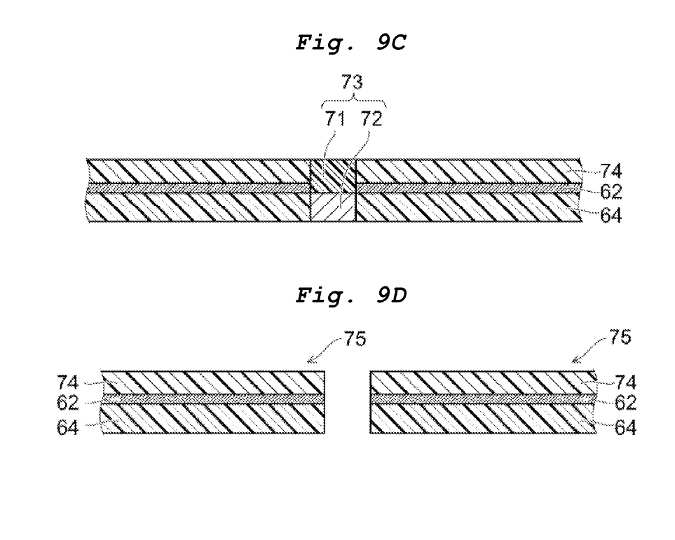

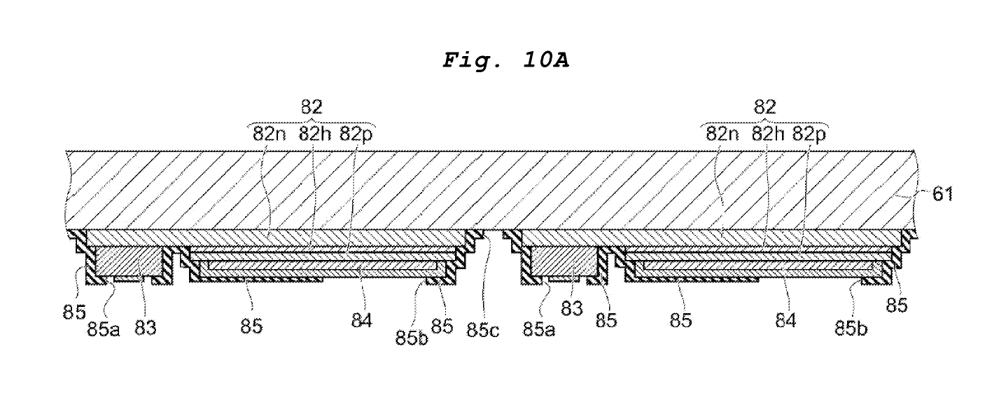

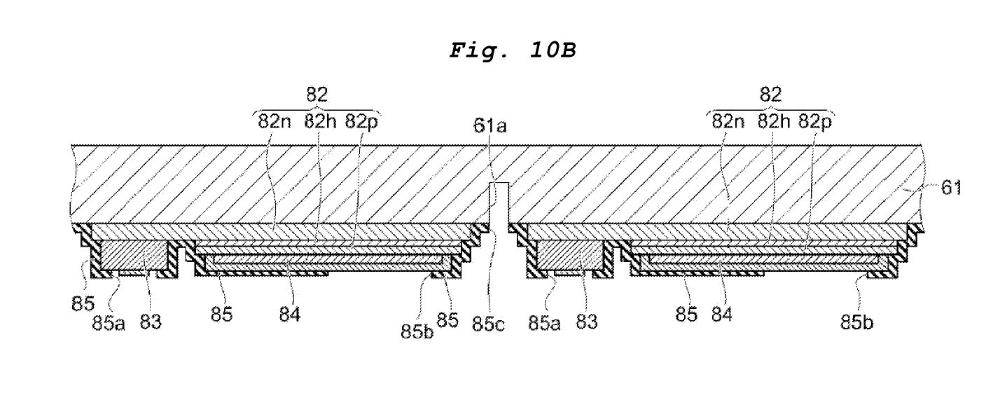

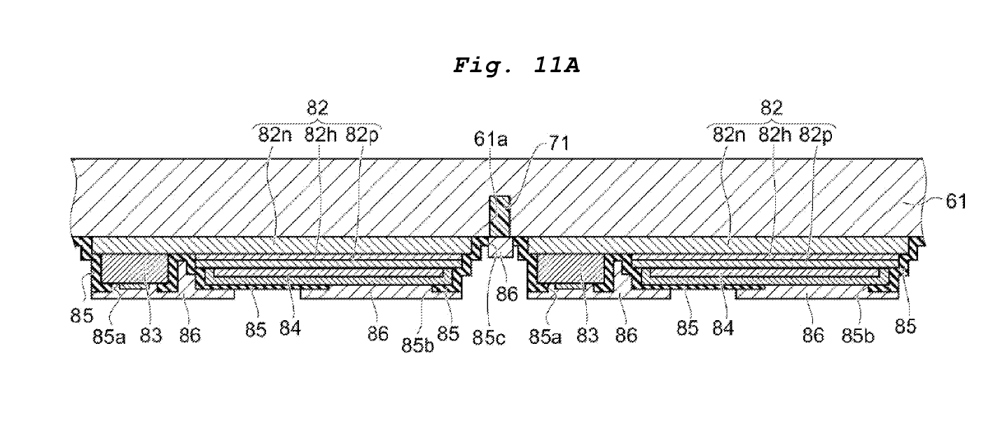

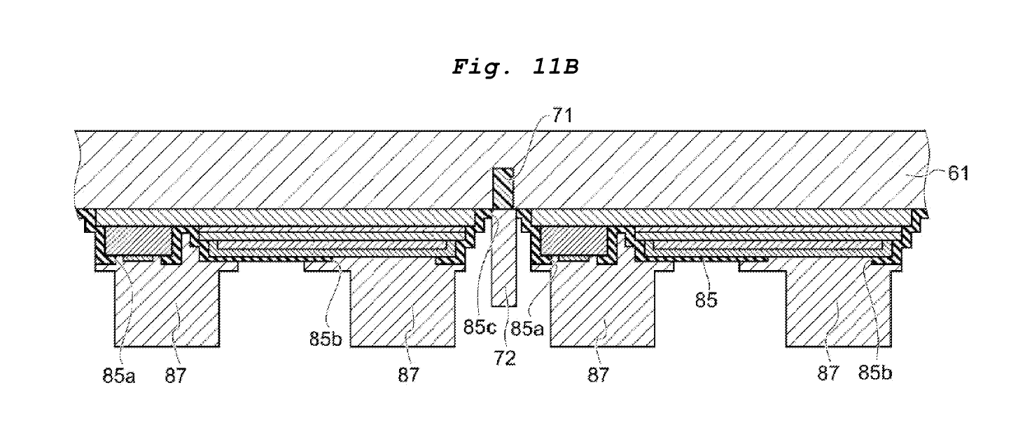

FIGS. 8A-8E and FIGS. 9A-9D are cross-sectional views illustrating processes in a manufacturing method of the semiconductor device according to a third embodiment.

In the explanation of the present embodiment, members similar to those of the second embodiment are identified with the same numerals and signs as in the second embodiment, and detailed explanation of processes similar to those in the second embodiment is omitted.

As shown in FIG. 8A, the semiconductor layer 62 is formed on the silicon substrate 61.

Then, as shown in FIG. 8B, for example, etching is carried out to form the trenches 62a on the semiconductor layer 62.

Then, as shown in FIG. 8C, etching is further carried out to form the trenches 61a in the upper layer portion of the silicon substrate 61. The trenches 61a are located in the regions right below the trenches 62a.

Then, as shown in FIG. 8D, embedding members 71 are embedded inside the trenches 61a and the trenches 62a. Then, protrusion members 72 are formed on the regions right above the trenches 62a. By the embedding members 71 and the protrusion members 72, wall-shaped members 73 are formed. The materials of the embedding members 71 and the protrusion members 72 are made of materials that can be easily separated in the later process, such as resin materials or metal materials. The types of the resin materials include the photosensitive resins and the thermoplastic resins. The metal material refers to one or several types of metals selected from the group consisting of copper, aluminum, titanium and nickel. As an example, the embedding members 71 are made of a resist material, and the protrusion members 72 are made of copper.

Then, as shown in FIG. 8E, on the semiconductor layer 62, a resin material is deposited to embed the protrusion members 72 to form the reinforcing substrate 64.

Then, as shown in FIG. 9A, the silicon substrate 61 (see FIG. 8E) is removed. As a result, the lower surface of the semiconductor layer 62 is exposed. Also, the embedding members 71 embedded in the trenches 61a on the silicon substrate 61 are exposed, and protrude downward from the lower surface of the semiconductor layer 62.

Then, as shown in FIG. 9B, a protective film 74 is formed on the lower surface of the semiconductor layer 62. In this case, the film thickness of the protective film 74 is less than the depth of the trenches 61a formed on the silicon substrate 61 (see FIG. 8C), and the protective film 74 does not embed the embedding members 71. That is, the protective film 74 is formed in the space surrounded by the embedding members 71. For example, suppose the semiconductor layer 62 is an LED layer, a film having phosphor dispersed in a transparent resin is formed as the protective film 74.

Then, as shown in FIG. 9C, by grinding the upper surface of the reinforcing substrate 64, the thickness is decreased, and the upper surface of the wall-shaped members 73 is exposed.

Then, as shown in FIG. 9D, for example, by carrying out etching, the wall-shaped members 73 are removed. As a result, the laminate including the reinforcing substrate 64, the semiconductor layer 62 and the protective film 74 is divided to individual pieces, and multiple semiconductor devices 75 are manufactured. For example, the semiconductor devices 75 are semiconductor light emitting devices that emit white color light.

Operations and effects of the present embodiment are explained below. According to the present embodiment, in the process shown in FIG. 8C, the trenches 61a are formed on the silicon substrate 61, and in the process shown in FIG. 8D, the embedding members 71 are embedded inside the trenches 61a. In the process shown in FIG. 9A, as the silicon substrate 61 is removed, the embedding members 71 protrude out from the lower surface of the semiconductor layer 62. Then, in the process shown in FIG. 9B, the protective film 74 is formed in the space surrounded by the embedding members 71. As a result, in the process shown in FIG. 9D, when the wall-shaped members 73 are removed, together with the reinforcing substrate 64 and the semiconductor layer 62, the protective film 74 is also separated. As a result, according to the present embodiment, it is possible to form the individual semiconductor devices 75 having the protective film 74 without carrying out dicing. The remaining features of the manufacturing method as well as the operation and effects in the present embodiment are the same as those in the second embodiment.

According to the present embodiment, as an example, as the protective film 74, a film having phosphor dispersed in a transparent resin is formed. However, the present disclosure is not limited to the scheme. For example, one may also adopt a scheme in which no phosphor is contained in the protective film 74. When the semiconductor layer 62 is not an LED layer, the protective film 74 may be made of a light shielding material. In each case, the protective film 74 works as a protective film in protecting the semiconductor layer 62.

### Fourth Embodiment

FIGS. 10A, 10B, 11A, 11B, 12A, 12B, 13A, 13B, and 14 are cross-sectional views illustrating an example of a manufacturing method of the semiconductor device according to a fourth embodiment.

In the explanation of the present embodiment, members similar to those of the third embodiment are identified with the same numerals and signs as in the third embodiment, and detailed explanation of processes similar to those in the third embodiment are omitted.

As shown in FIG. 10A, a semiconductor layer 82 is formed on the silicon substrate 61. Here, the semiconductor layer 82 is formed by sequentially laminating an n-type layer 82n, a light emitting layer 82h, and a p-type layer 82p. Then, the semiconductor layer 82 is divided to individual pieces as the prescribed regions in the later processes. Then, an n-type electrode 83 coupled to the n-type layer 82n is formed, and, at the same time, a p-type electrode 84 coupled to the p-type layer 82p is formed.

Then, an insulating film 85 is formed on the entire surface. Then, by selectively remove the insulating film 85, an opening portion 85a is formed on the upper surface of the n-type electrode 83, and an opening portion 85b is formed on the upper surface of the p-type electrode 84, and an opening portion 85c is formed in each prescribed region as the dividing region between the semiconductor devices. The opening portion 85c is formed to surround the prescribed region as each semiconductor device.

Then, as shown in FIG. 10B, for example, etching is carried out to form the trenches 61a in the upper layer portion of the silicon substrate 61. The trenches 61a are located at the regions right below the opening portions 85c.

Then, as shown in FIG. 11A, the embedding members 71 are embedded inside the trenches 61a. For example, the embedding members 71 may be made of a resist material. Also, the embedding members 71 may be made of a metal material.

Then, a seed layer 86 is formed in the region including the interior of the opening portion 85a of the insulating film 85 and the region right above this interior region, the region including the interior of the opening portion 85b and the region right above this interior region, and the region including the interior of the opening portion 85c and the region right above this interior region, respectively.

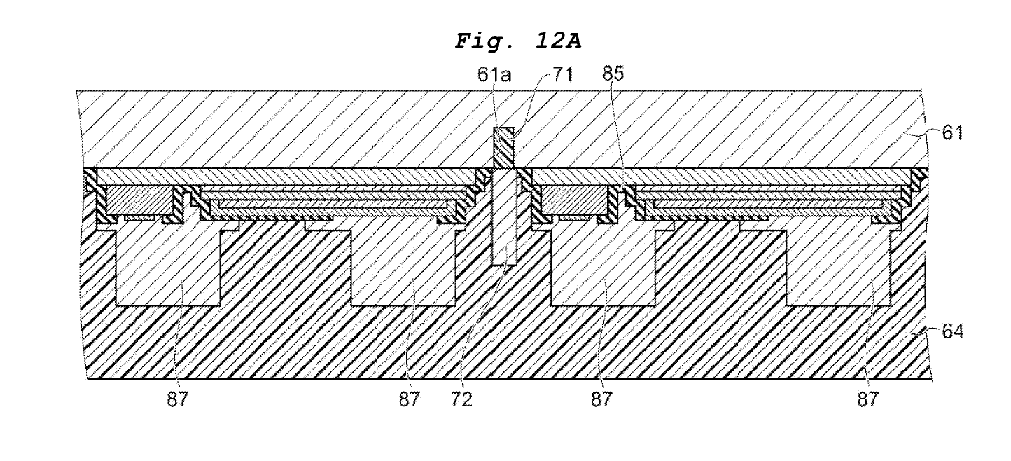

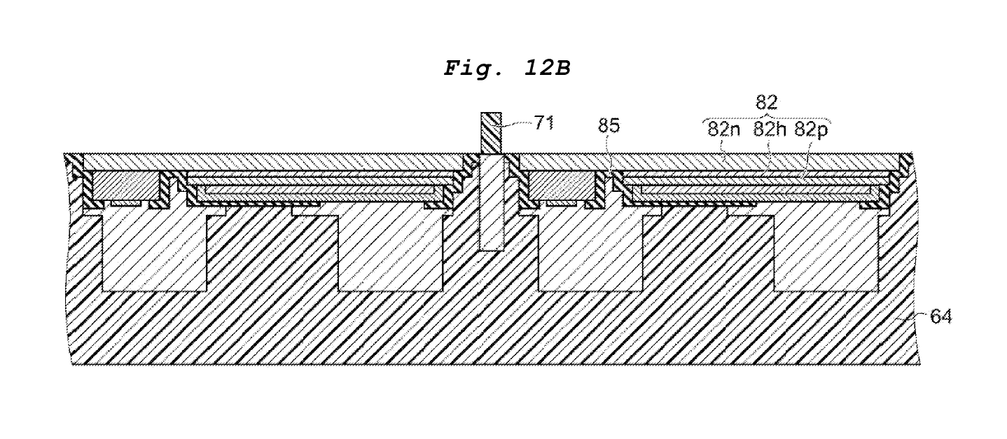

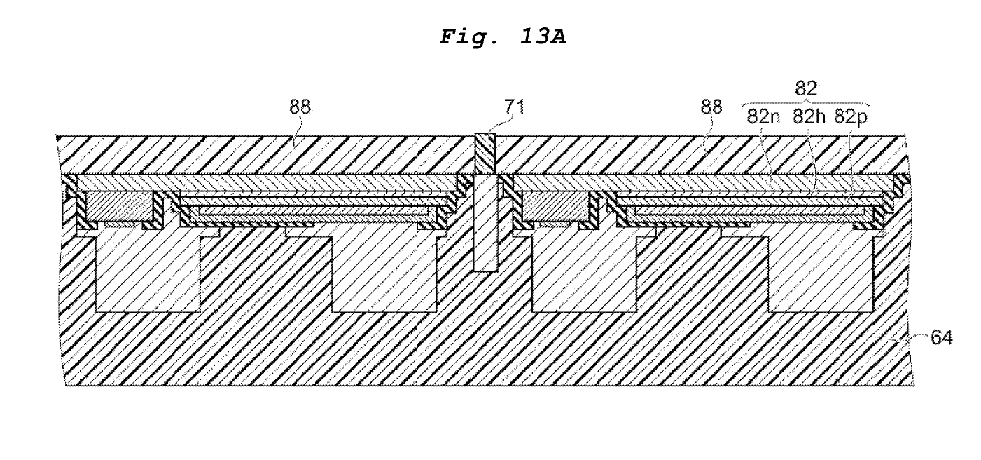

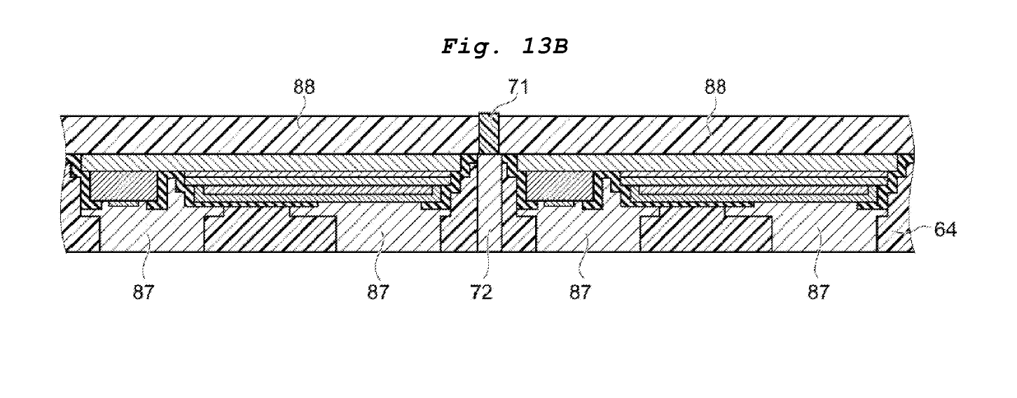

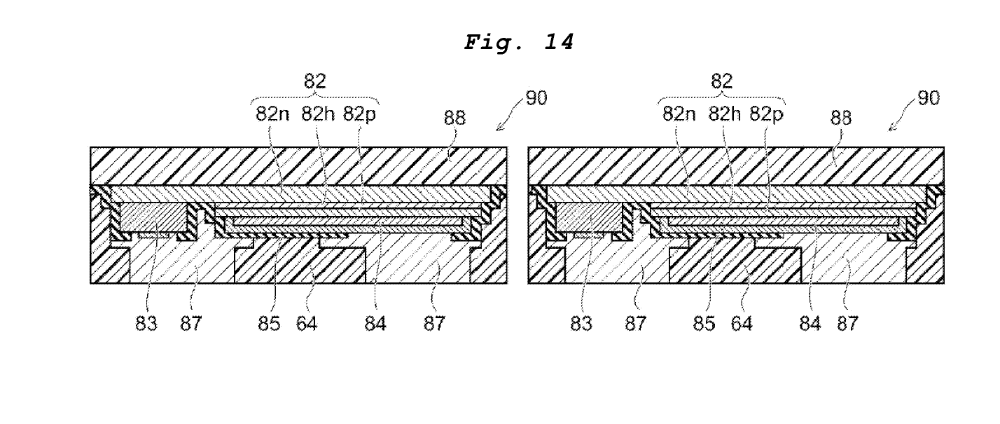

Then, as shown in FIG. 11B, electroplating of a metal material, such as copper is carried out. As a result, copper is deposited on the seed layer 86. As a result, the electrodes 87 made of copper are formed in the regions including the regions right above the opening portions 85a of the insulating film 85 and the regions including the regions right above the opening portions 85b, respectively. Then, protrusion members 72 made of copper are formed on the regions including the regions right above the opening portions 85c. That is, in this process, the electrodes 87 and the protrusion members 72 are formed at the same time. Also, in this plating operation, the plating rate is lower in the initial stage, and the plating rate is then increased. As in the first embodiment, the crystal grain size of the portion of the electrodes 87 on the side near the semiconductor layer 82 is made smaller, and the crystal grain size in the portion on the side opposite to the semiconductor layer 82 is made larger. As shown in FIG. 11B, the seed layer 86 is shown as a portion of the electrodes 87 and the protrusion members 72. There is the same feature in FIG. 12A and FIG. 12B, FIG. 13A and FIG. 13B, and FIG. 14.

Then, as shown in FIG. 12A, on the insulating film 85, a resin material is deposited to embed the protrusion members 72 and electrodes 87 to form the reinforcing substrate 64.

Then, as shown in FIG. 12B, the silicon substrate 61 is removed. As a result, the lower surface of the semiconductor layer 82 is exposed. Also, the embedding members 71 embedded in the trenches 61a of the silicon substrate 61 are exposed, and protrude downward from the lower surface of the semiconductor layer 82.

Then, as shown in FIG. 13A, a protective film 88 is formed on the lower surface of the semiconductor layer 82. In this case, the protective film 88 is formed in the space surrounded by the embedding members 71. According to the present embodiment, a film with phosphor dispersed in a transparent resin is formed as the protective film 88.

Then, as shown in FIG. 13B, the upper surface of the reinforcing substrate 64 is ground to expose the upper surface of the protrusion members 72 and the electrodes 87.

Then, as shown in FIG. 14, for example, etching is carried out to remove the embedding members 71 made of a resist material and the protrusion members 72 made of copper. As a result, the laminate including the reinforcing substrate 64, the semiconductor layer 82 and the protective film 88 is divided to individual pieces, so that multiple semiconductor devices 90 are manufactured. For example, the semiconductor devices 90 are semiconductor light emitting devices that emit white color light.

In the semiconductor device 90 manufactured in this way, the semiconductor layer 82 is arranged by laminating the n-type layer 82n, the light emitting layer 82h and the p-type layer 82p in order, and, on the semiconductor layer 82, the n-type electrode 83 and p-type electrode 84 are arranged separated from each other. The n-type electrode 83 is coupled to the n-type layer 82n of the semiconductor layer 82, and the p-type electrode 84 is coupled to the p-type layer 82p of the semiconductor layer 82. The insulating film 85 covers the entirety of the upper surface of the semiconductor layer 82, the entirety of the side surface and a portion of the upper surface of the n-type layer 82n, the entirety of the side surface of the light emitting layer 82h, and the entirety of the side surface and a portion of the upper surface of the p-type layer 82p. The electrodes 87 are arranged on the n-type electrode 83 and the p-type electrode 84, respectively, and are coupled to the n-type electrode 83 and p-type electrode 84, respectively. On the periphery and between the electrodes 87, the reinforcing substrate 64 made of a resin material is arranged. The upper surface of the electrodes 87 is exposed on the upper surface of the reinforcing substrate 64. On the other hand, the protective film 88 is arranged on the lower surface of the semiconductor layer 82. As the protective film 88, phosphor is dispersed in a transparent resin.

In the following, the operation and effects of the present embodiment are explained below.

According to the present embodiment, in the process shown in FIG. 11B, the protrusion members 72 are formed at the same time as the electrodes 87. As a result, there is no need to arrange a process used solely for formation of the protrusion members 72, and it is possible to suppress increase in the manufacturing cost of the semiconductor device 90.

According to the present embodiment, the crystal grain size in the portion of the electrodes 87 near the side of the semiconductor layer 82 is made smaller, and the crystal grain size in the portion on the side opposite to the semiconductor layer 82 is made larger. As a result, just as the first embodiment, it is possible to guarantee a high productivity of the semiconductor device 90, and it is possible to improve the durability to the thermal stress. The remaining features of the manufacturing method as well as the operation and effects of the present embodiment are the same as those in the third embodiment.

According to the embodiment, it is possible to realize a semiconductor device with a high durability to the thermal stress and a manufacturing method of the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer; and
one or more electrodes coupled to the semiconductor layer, wherein at least one electrode includes a first end portion that is formed to have crystals of a first grain size and a second end portion that is formed to have crystals of a second grain size that is larger than the first grain size, and the first end portion is disposed between the semiconductor layer and the second end portion.

2. The semiconductor device of claim 1, wherein the crystals are formed from electroplating of copper.

3. The semiconductor device of claim 1, wherein the at least one electrode is formed by an electroplating method, and wherein an electroplating rate used to form the first end portion is lower than an electroplating rate used to form the second end portion.

4. The semiconductor device of claim 1, further comprising a sealing resin body that covers the semiconductor layer and the one or more electrodes.

5. The semiconductor device of claim 1, wherein the semiconductor layer is a light emitting device layer.

6. The semiconductor device of claim 5, wherein the semiconductor layer contains a nitride of a group-III element.

7. The semiconductor device of claim 6, wherein the semiconductor layer contains gallium nitride.

8. The semiconductor device of claim 1, wherein the second end portion is soldered to a wiring layer of an assembling substrate.

9. The semiconductor device of claim 1, further comprising a metal film formed on an end surface of the second end portion, the metal film including a nickel layer and a gold layer.

10. The semiconductor device of claim 9, wherein the metal film further includes a palladium layer.

11. A method for manufacturing a semiconductor device, the method comprising:
forming a semiconductor layer on a first substrate;
forming trenches to divide the semiconductor layer into several portions in the semiconductor layer;
forming a wall-shaped member in the interior and upper portion of the trenches;
forming a second substrate on the semiconductor layer;
removing the first substrate; and
removing the wall-shaped member.

12. The method of claim 11, wherein the wall-shaped member includes a material selected from the group consisting of photosensitive resins and thermoplastic resins.

13. The method of claim 11, wherein the wall-shaped member includes a material selected from the group consisting of copper, aluminum, titanium and nickel.

14. The method of claim 11, further comprising forming a protective film on a lower surface of the semiconductor layer before removing the wall-shaped member, wherein a thickness of the protective film is less than a depth of the trenches formed on the first substrate.

15. The method of claim 11, wherein said forming the wall-shaped member includes:
embedding a first member in the trenches; and
forming a second member on the first member,
wherein the first member includes a material selected from the group consisting of a photosensitive resin and a thermoplastic resin, and the second member includes a material selected from the group consisting of copper, aluminum, titanium and nickel.

16. The method of claim 11, further comprising:
forming a protective film on a lower surface of the semiconductor layer before removing the wall-shaped member,
wherein the semiconductor layer is a light emitting device layer, and
wherein the protective film is a film formed by dispersing a phosphor in a transparent resin.

17. The method of claim 11, wherein the wall-shaped member is exposed on an upper surface of the second substrate right before removal of the wall-shaped member.

18. The method of claim 11, wherein the first substrate is made of a material selected from the group consisting of silicon, gallium arsenide, alumina and gallium oxide.

19. The method of claim 11, wherein the semiconductor layer contains InₓAl_{y}Ga_{z}N, and wherein x+y+z=1.

20. A method for manufacturing a semiconductor device, the method comprising:
forming a semiconductor layer; and
forming a first electrode portion on the semiconductor layer by a first electroplating method; and
forming a second electrode portion on the first electrode portion by a second electroplating method,
wherein an electroplating rate of the first electroplating method is lower than an electroplating rate of the second electroplating method.
